(19) United States
(12) Patent Application Publication
(10) Pub. No.: US 2003/0119325 A1
(43) Pub. Date: Jun. 26, 2003

(54) Method of forming a metal line in a semiconductor device

(76) Inventors: Cheol Mo Jeong, Ichon-Shi (KR); Pyeng Geun Sohn, Ichon-Shi (KR)

Correspondence Address: Jacobson Holman, 400 Seventh Street, N.W., Washington, DC, 20004-2218, US

(21) Appl. No.: 10/286,943

(22) Filed: Nov. 4, 2002

(30) Foreign Application Priority Data
Dec. 22, 2001 (KR) 2001-83501

(51) Int. Cl. H01L 21/311

(52) U.S. Cl. 438/694

(57) ABSTRACT

The present invention relates to a method of forming a metal line in a semiconductor device. Upon a process of forming a barrier metal layer of Ti/TiN using an ion metal plasma (IMP) method, an increased AC bias power is applied to increase a deposition thickness of Ti/TiN at an edge portion of the bottom of a contact hole. Therefore, it is possible to prevent penetration of fluorine ions into the semiconductor substrate upon a process of depositing a subsequent tungsten layer.

### BACKGROUND OF THE INVENTION

1. Field of the Invention

The invention relates generally to a method of forming a metal line in a semiconductor device, and more particularly to, a method of forming a barrier metal layer using an ion metal plasma (IMP) method.

2. Description of the Prior Art

Recently, in metal lines used for signal transfer and power application in a semiconductor device, the line width itself and distance between them are increasingly narrowed due to an increased level of integration. Along with this trend, various methods for forming the metal lines have been attempted. A material for the metal lines usually include aluminum (Al), copper (Cu) and an alloy layer of them. A material for the metal lines is buried into the contact hole through which a given junction is exposed to form a metal line having a desired thickness and width. Further, in order to improve a defective contact hole burial characteristic of the material for the metal line, a tungsten (W) plug is formed within the contact hole and the metal line is then formed on it.

In this case, however, a junction-spiking phenomenon occurs since the aluminum metal layer or tungsten plug and silicon (Si) of the semiconductor substrate reacts at the bottom of the contact hole. As a result, this junction spiking causes to degrade an electrical characteristic and reliability of the semiconductor device. Therefore, in order to prevent the junction-spiking phenomenon, an interlayer insulating film (ILD) is formed. Also, in order to prevent diffusion of silicon (Si) ions of the semiconductor substrate on an inner surface of the contact hole that is buried by the tungsten layer, a barrier metal (B/M) layer is formed. The barrier metal layer has a structure on which titanium (Ti) and a titanium nitride film (TiN) are stacked.

The method of forming the barrier metal layer having the stack structure of the Ti/TiN films comprises a conventional Ti/TiN method, a collimated Ti/conventional TiN method, an IMP Ti/chemical vapor deposition (CVD) TiN method, an IMP Ti/IMP TiN (at this time, AC bias power is not applied) or an IMP Ti/collimated TiN method.

FIG. 1 is shows a profile of the barrier metal layer that can be obtained when the barrier metal layer is formed using the conventional Ti/TiN method and the collimated Ti/conventional TiN method.

Referring now to FIG. 1, in case of using the conventional Ti/TiN method, an interlayer insulating film 12 is formed on a semiconductor substrate 10 including a given memory cell and a transistor having a gate and a junction region. Photolithography and etch processes are then performed to form a contact hole 14 through which a given portion of the semiconductor substrate 10 is opened. Next, a Ti film 16a and a TiN film 16b are sequentially deposited on the entire structure including the contact hole 14 by the conventional method by which Ti and TiN targets are sputtered with strike using argon (Ar) gas, thus forming a barrier metal layer 16.

On the other hand, in case of using the collimated Ti/conventional TiN method, the contact hole 14 is formed in the semiconductor substrate 10. Next, Ti is sputtered with strike using Ar gas. At this time, the Ti film 16a is formed using the collimated method by which only particles having the straightness among the Ti particles are sputtered by the argon gas. Then, the TiN film 16b is deposited on the Ti film 16a by the conventional method, thus forming the barrier metal layer 16.

As described above, in case of using the conventional Ti/TiN method and the collimated Ti/conventional TiN method, the barrier metal layer 16 could not have a sufficient step coverage of the Ti film 16a at an edge portion (A1) of the bottom of the contact hole 14 since the size of the contact hole 14 formed in the interlayer insulating film 12 is reduced due to an increased level of integration of the semiconductor device. As a result, there is a problem that the contact resistance is increased to cause a defect in the semiconductor device.

Further, even in case of the TiN film 16b, a sufficient step coverage characteristic could not be obtained at the edge portion (A1) of the bottom of the contact hole 14. A keyhole is generated within a tungsten layer (not shown) due to an overhang phenomenon at the top portion of the side of the TiN film 16b formed on the inner surface of the contact hole 14 when the tungsten layer is later buried. As a result, there is a problem that an electrical characteristic and reliability of the device is degraded.

Therefore, in the conventional Ti/TiN method and the collimated Ti/conventional TiN method, fluorine (F) ions react with silicon (Si) ions of the semiconductor substrate when tungsten is deposited since the step coverage of the Ti/TiN film is weaken at the edge portion of the bottom of the contact hole. Therefore, there is a problem that tungsten is penetrated into the semiconductor substrate, like a portion (A3) in FIG. 3. Further, there is a fail problem in the device due to an increased contact resistance since the F ions are penetrated into the bottom of the TiSi₂ layer at the bottom of the contact hole, thus forming an amorphous layer.

FIG. 2 shows a profile of the barrier metal layer that can be obtained when the barrier metal layer is formed using the IMP Ti/CVD TiN method and the IMP Ti/IMP TiN method.

Referring now to FIG. 2, in case of using the IMP Ti/CVD TiN method, an interlayer insulating film 22 is formed on a semiconductor substrate 20. Photolithography and etch processes are then performed to form a contact hole 24 through which a given portion of the semiconductor substrate 20 is opened. Next, a Ti film 26a is formed by the IMP method and a TiN film 26b is also formed on the Ti film 26a by the CVD method using a TDEAT+NH₃ source. Thereafter, the bottom portion of the contact hole 24 formed in the interlayer insulating film 22 is crystallized by plasma treatment. As a result, the step coverage of respective films can be improved.

On the other hand, the IMP Ti/IMP TiN method is one by which the Ti film 26a and the TiN film 26b are sequentially deposited, by means of the IMP method, on the semiconductor substrate 20 in which the contact hole 24 is formed, thus forming the barrier metal layer 26.

As described above, in case of using the IMP Ti/CVD TiN method and the IMP Ti/IMP TiN method, the sidewall of the contact hole remains intact as an amorphous phase. Thus, upon a subsequent anneal process, the TiN film 26b at an portion (A2) of the bottom of the contact hole could not be formed consecutively. Due to this, upon a subsequent deposition process of the tungsten layer, tungsten is easily penetrated into the edge portion of the bottom of the contact hole, like (A4) in FIG. 4. A dielectric film is thus formed at the edge portion since the F ions and SI ions of the semiconductor substrate react. As a result, there is a problem that the contact resistance is increased to cause fail of the device. In addition, as the step coverage at the sidewall of the contact hole is very weak, a F-radical of the F ions reacts with the Si ions of the semiconductor substrate upon deposition of the tungsten layer, thus forming SiF₄. As a result, this hinders a subsequent process of burying the tungsten layer.

As described above, a device fail occurring when the prior art conventional Ti/TiN method, the collimated Ti/conventional TiN method, the IMP Ti/CVD TiN method and the IMP Ti/IMP TiN method are employed will be described by reference to FIG. 5A and FIG. 5B.

FIG. 5A and FIG. 5B show characteristics for explaining a function fail of a device due to degraded characteristic of transconductance (1/R) occurring according to the profiles shown in FIGS. 3 and 4.

As can be seen from FIG. 5A, in case that a fail cell (FC) is generated due to penetration of the F ions, there is almost no variation in the cell drain current depending on the cell voltage (Vpx). On the other hand, in case of a normal cell (NC) into which the F ions are not penetrated, the cell drain current is abruptly changed at a given threshold voltage. Meanwhile, if the FC is generated by an increased contact resistance at the bottom of the contact hole due to penetration of the F ions, variations in the current amount applied to a neighboring cell gate electrode is reduced when the cell gate voltage is sweep, thus generating a 2-bit row maximum gradient (GM) cell.

Further, as can bee seen from FIG. 5B, in case of the NC, the threshold voltage is kept at a constant range (4.5V through 5V). On the other hand, in case of the FC, the threshold voltage is increased to 5.5V through 9.9V.

### SUMMARY OF THE INVENTION

The present invention is contrived to solve the above problems and an object of the present invention is to provide a method of forming a metal line in semiconductor device by which an increased AC bias power is applied to increase a deposition thickness of Ti/TiN at an edge portion of the bottom of a contact hole upon a process of forming a barrier metal layer of Ti/TiN using an IMP method, so that penetration of fluorine ions into a semiconductor substrate can be prevented upon a subsequent process of depositing a tungsten layer.

In order to accomplish the above object, a method of forming a metal line in a semiconductor device according to the present invention, is characterized in that it comprises the steps of forming an interlayer insulating film on a semiconductor substrate in which a given structure is formed; etching the interlayer insulating film to form a contact hole; forming a barrier metal layer on an inner surface of the contact hole, wherein a profile of the barrier metal layer is decided by applying an AC bias power; and forming a contact plug by which the contact hole is buried and then forming a metal line on the entire structure.

### BRIEF DESCRIPTION OF THE DRAWINGS

The aforementioned aspects and other features of the present invention will be explained in the following description, taken in conjunction with the accompanying drawings, wherein:

FIG. 1 is shows a profile of a barrier metal layer that can be obtained when the barrier metal layer is formed using a conventional Ti/TiN method and a collimated Ti/conventional TiN method;

FIG. 2 shows a profile of a barrier metal layer that can be obtained when the barrier metal layer is formed using an IMP Ti/CVD TiN method and an IMP Ti/IMP TiN method;

FIG. 3 is TEM illustrating a profile of a fail cell depending on the profile of the barrier metal layer shown in FIG. 1;

FIG. 4 is TEM illustrating a profile of a fail cell depending on the profile of the barrier metal layer shown in FIG. 2;

FIG. 5A and FIG. 5B show characteristics for explaining a function fail of a device due to degraded characteristic of transconductance (1/R) occurring according to the profiles shown in FIGS. 3 and 4;

FIG. 6A through FIG. 6C are cross-sectional views of semiconductor devices for describing a method of manufacturing the semiconductor devices according to a preferred embodiment of the present invention; and

FIG. 7A through FIG. 7C are cross-sectional views of the semiconductor devices illustrating a profile of a barrier metal layer depending on an AC bias power.

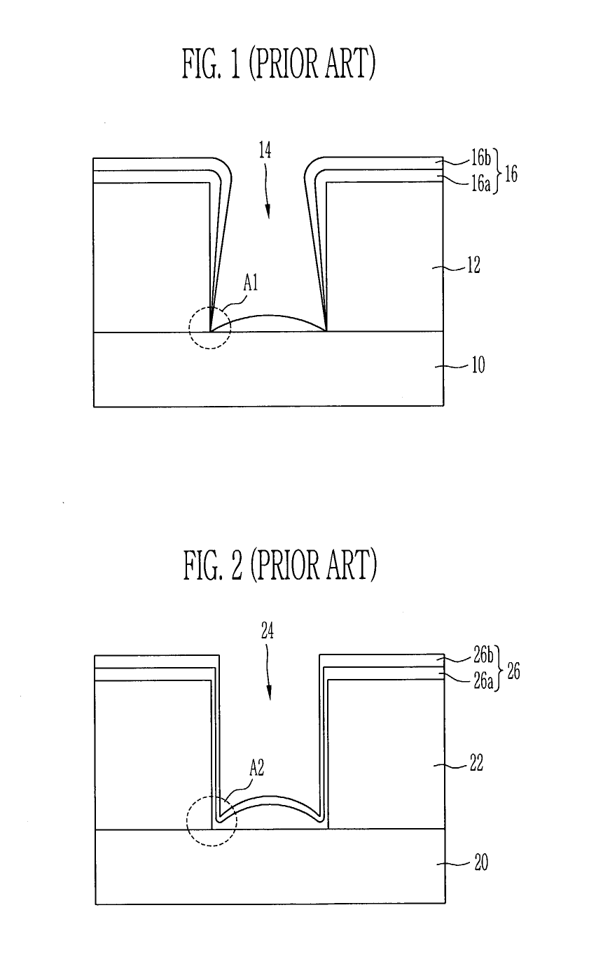

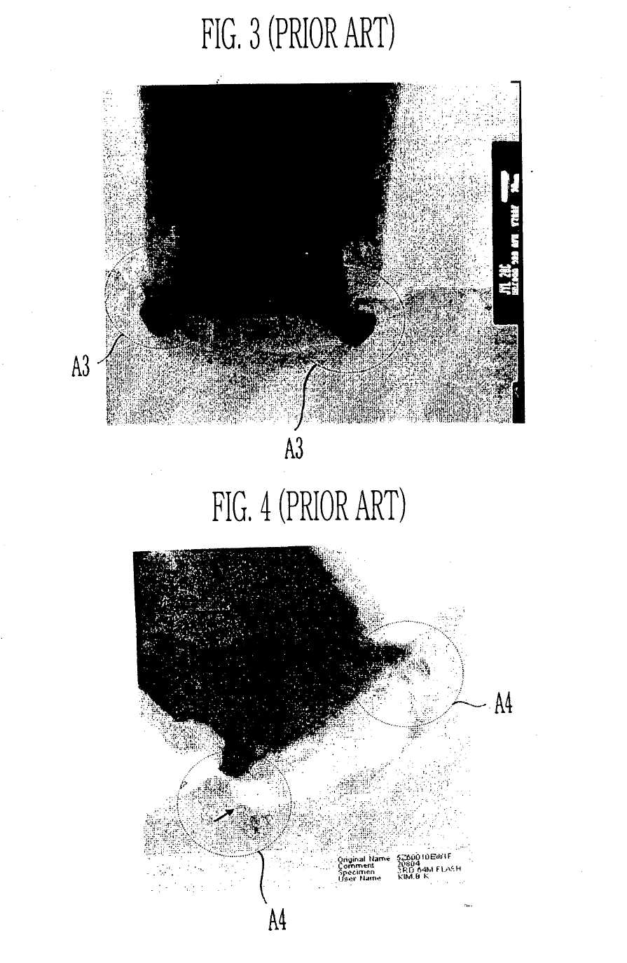

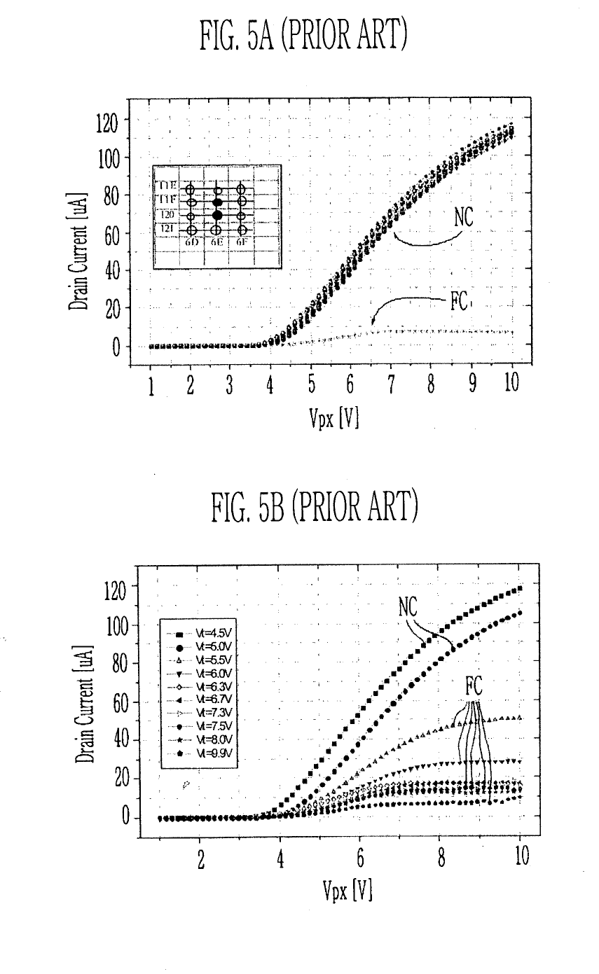

### DETAILED DESCRIPTION OF PREFERRED EMBODIMENTS

The present invention will be described in detail by way of a preferred embodiment with reference to accompanying drawings.

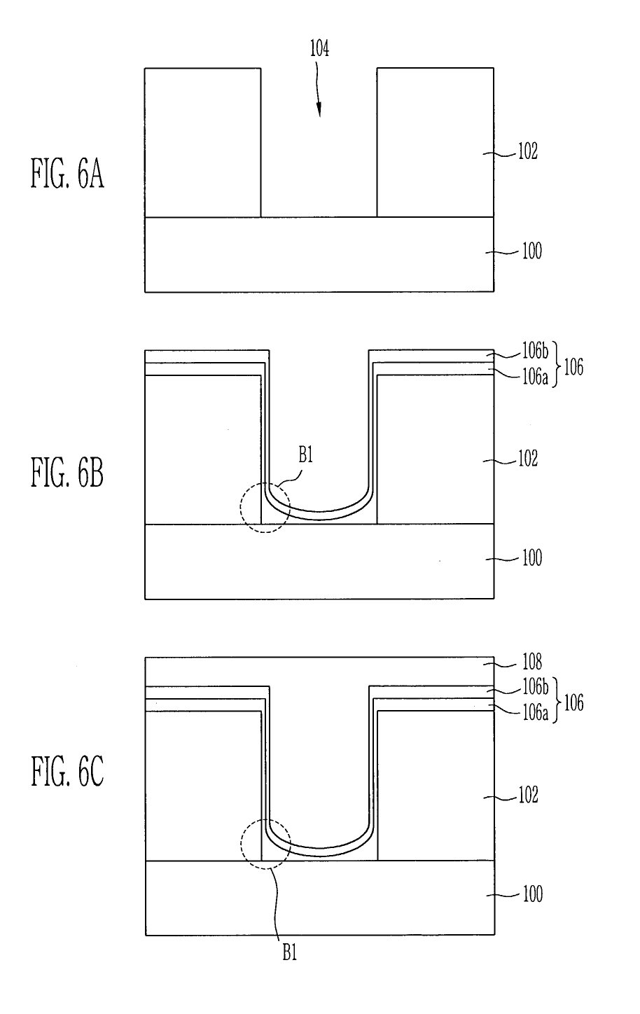

FIG. 6A through FIG. 6C are cross-sectional views of semiconductor devices for describing a method of manufacturing the semiconductor devices according to a preferred embodiment of the present invention.

Referring now to FIG. 6A, an interlayer insulating film 102 is formed on a semiconductor substrate 100 in which a gate electrode and a junction region (not shown) for forming a memory cell and a transistor are formed. A chemical mechanical polishing (CMP) process is then implemented to planarize the interlayer insulating film 102.

Next, after a photoresist is covered on the entire structure, an exposure process using a photo mask is implemented to form a photoresist pattern (not shown) through which a given portion of the semiconductor substrate 100 is opened. Thereafter, an etch process using the photoresist pattern as a etch mask is implemented to form a contact hole 104 through which a given portion of the semiconductor substrate 100 is opened.

By reference to FIG. 6B, particles remaining on an inner surface of the contact hole 104 are removed by a given cleaning process in order to improve an interfacial characteristic on the inner surface of the contact hole 104. Next, in order to prevent a junction-spiking phenomenon occurring at the interface of the semiconductor substrate 100 and a metal film by which the contact hole 104 is buried due to a reaction between them, a Ti film 106a and a TiN film 106b are sequentially deposited on the inner surface of the contact hole 104 and on the interlayer insulating film 102, thus forming a barrier metal layer 106.

At this time, the barrier metal layer 106 may be formed by depositing the Ti film 106a and the TiN film 106b in a single chamber, or by independently depositing them in two chambers. In general, a deposition equipment may include “Endura System” manufactured by AMAT, Inc. by which IMP Ti/IMP TiN recipe tuning can be easily used.

In case that the Ti film 106a and the TiN film 106b are deposited using the single chamber, the Ti film 106a is first deposited by applying a DC power of 1.5 through 3.0 KW, a RF power of 1.5 through 3.0 KW and an AC bias power of 200 through 500W in a state that the pressure of the chamber is kept 10 through 50 mTorr. Next, the TiN film 106b is deposited on the Ti film 106a by injecting a N₂ gas into the chamber in a state that the condition within the chamber is kept to be almost same to the deposition condition of the Ti film 106a. During the process of depositing the TiN film 106b, the pressure of the chamber is kept 20 through 100 mTorr by the N₂ gas injected into the chamber. At this time, in order for the deposition target of the Ti film 106a to be 50 through 100 Å in thickness based on the bottom of the contact hole 104, the Ti film 106a is deposited 100 through 500 Å in thickness based on the semiconductor substrate 100.

On the other hand, in case that the Ti film 106a and the TiN film 106b are deposited using the two chambers, the Ti film 106a is first deposited by applying a DC power of 1.5 through 3.0 KW, a RF power of 1.5 through 3.0 KW and an AC bias power of 200 through 500W in a state that the pressure of the first chamber is kept 10 through 50 mTorr. Next, the TiN film 106b is deposited on the Ti film 106a with the same condition to that in the first chamber but additionally the semiconductor substrate 100 moved to the second chamber into which a N₂ gas is injected.

At this time, the pressure of the second chamber is kept 20 through 100 mTorr by the N₂ gas. Further, in order for the deposition target of the Ti film 106a to be 50 through 100 Å in thickness based on the bottom of the contact hole 104, the Ti film 106a is deposited 100 through 500 Å in thickness based on the semiconductor substrate 100.

Meanwhile, in case that the Ti film 106a and the TiN film 106b are deposited in the single chamber, a film that is finally deposited within the chamber consists of the Ti film/TiN film and the Ti film. At this time, if the deposition process is completed in the N₂ gas upon a pre-wafer process, the TiN film is firstly deposited on a subsequent wafer (i.e., new wafer) than the Ti film when the new wafer is introduced into the chamber in order to form the barrier metal layer. This causes to degrade an electrical characteristic. The reason is because the deposition process is completed in a state that the N₂ gas is precluded after the TiN film is deposited. At this time, the Ti film deposited on the TiN film is changed to the TiN film by a subsequent annealing process using a N₂ gas.

Referring now to FIG. 6C, a given annealing process is implemented to anneal the barrier metal layer 106. Next, a tungsten layer 108 is deposited on the contact hole 104 and the barrier metal layer 106 so that the contact hole 104 is buried. Though not shown in the drawing, the tungsten layer 108 is etched back so that the TiN film 106b formed on the interlayer insulating film 102 is exposed. In a state that an aluminum metal film is deposited on the TiN film 106b and the tungsten layer 108, the aluminum metal film and the barrier metal layer 106 are patterned to form a metal line.

As described above, the process of depositing the Ti film 106a and the TiN film 106b for forming the barrier metal layer 106 is performed using the IMP method. At this time, in order to obtain a profile such as “B1” in FIG. 6B, it is required that the AC bias power of over a given amount be applied upon the deposition process. The reason why an increased AC bias power is applied is to overcome the conventional problems by enhancing a characteristic of the barrier metal layer 106 and thickly forming the TiN film 106b formed at the edge portion of the bottom of the contact hole 104.

As such, the AC bias power in the IMP Ti/IMP TiN method is the most important factor in determining a profile of the barrier metal layer.

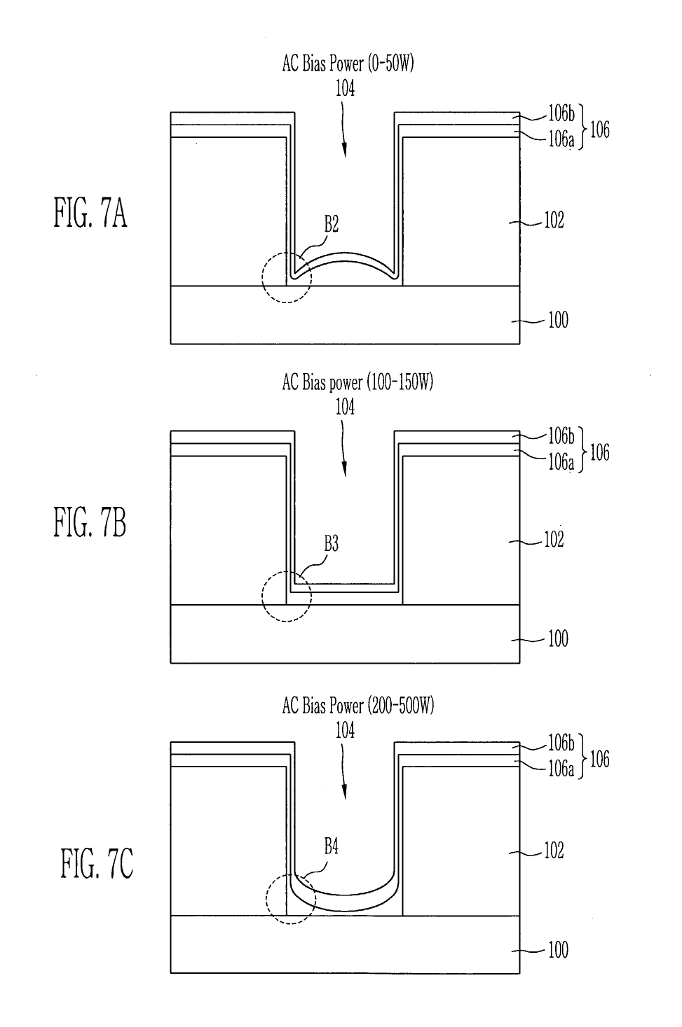

Variation in the profile of the barrier metal layer depending on the amount of the AC bias power will be now described in detail by reference to FIG. 7A through FIG. 7C.

Referring now to FIG. 7A, there is shown a profile of the barrier metal layer when the AC bias power of 0 through 50W is applied. From the drawing, it can be seen that the edge portion “B2” at the bottom of the contact hole 104 has the same profile to that of the barrier metal layer 106 that is deposited by a metal deposition process using a common physical vapor deposition (PVD) method. Thereby, the same problems in the conventional barrier metal layer occur.

By reference to FIG. 7B, there is shown a profile of the barrier metal layer when the AC bias power of 100 through 150W is applied. From the drawing, it can be seen that the portion “B2” protruded at the center of the bottom of the contact hole 104 as shown in FIG. 7A is made to be a constant size like an edge portion “B3” by applying an increased AC bias power of 100W through 150W.

Referring now to FIG. 7C, there is shown a profile of the barrier metal layer when the AC bias power of 200 through 500W is applied. Unlike the profile “B3” in FIG. 7B, it can be seen that an edge portion “B4” at the bottom of the contact hole 104 has a concave profile. The reason is because the barrier metal layer 106 is thickly formed at the edge portion “B4” and the side portion of the bottom of the contact hole 104 since a previously deposited layer is re-sputtered by Ti ions having a high energy due to a high AC bias power while they collide against the Ti film or the TiN film at the bottom of the contact hole.

As mentioned above, according to the present invention, when the barrier metal layer of Ti/TiN is formed using the IMP method, an increased AC bias power is applied to increase a deposition thickness of Ti/TiN at the edge portion of the bottom of the contact hole. Therefore, the present invention has an advantage that it can prevent penetration of fluorine (F) ions into the semiconductor substrate upon a process of depositing a subsequent tungsten layer.

Further, the AC bias power is adequately controlled upon the process of forming the barrier metal layer using the IMP method. Therefore, the present invention has an advantage that it can prevent fail of a device, improve a characteristic of the device and increase the yield since penetration of fluorine (F) ions into the semiconductor substrate can be prevented upon a process of depositing a subsequent tungsten layer.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A method of forming a metal line in a semiconductor device, comprising the steps of:
forming an interlayer insulating film on a semiconductor substrate in which a given structure is formed;
etching the interlayer insulating film to form a contact hole;
forming a barrier metal layer on an inner surface of the contact hole, wherein a profile of the barrier metal layer is determined by applying an AC bias power to have a concave profile in a bottom of the contact hole; and
forming a contact plug by which the contact hole is buried and then forming a metal line on the entire structure.

2. The method as claimed in claim 1, wherein said AC bias power is 200 through 500W.

3. The method as claimed in claim 1, wherein said barrier metal layer is formed to have a stack structure of a Ti film and a TiN film by means of an ion metal plasma method using a single chamber.

4. The method as claimed in claim 3, wherein said Ti film is deposited in thickness of 100 through 500 Å, by applying a DC power of 1.5 through 3.0 KW, a RF power of 1.5 through 3.0 KW and an AC bias power of 200 through 500W in a state that a pressure of the chamber is kept 10 through 50 mTorr.

5. The method as claimed in claim 3, wherein said TiN film is formed to have a stack structure of first and second TiN films by performing the steps of:
injecting a N₂ gas into the chamber to deposit the fist TiN film in a state that a condition within the chamber is kept to be same to the deposition condition of the Ti film;
precluding the N₂ gas injected into the chamber to deposit the Ti film on the first TiN film; and
performing an annealing process using the N₂ gas to change the Ti film to the second TiN film.

6. The method as claimed in claim 1, wherein said barrier metal layer is formed to have a stack structure of a Ti film and a TiN film by means of an ion metal plasma method using first and second chambers.

7. The method as claimed in claim 6, wherein said Ti film is deposited in thickness of 100 through 500 Å, by applying a DC power of 1.5 through 3.0 KW, a RF power of 1.5 through 3.0 KW and an AC bias power of 200 through 500W in a state that a pressure of the first chamber is kept 10 through 50 mTorr.

8. The method as claimed in claim 6, wherein said TiN film is deposited on the Ti film with the same condition to that in the first chamber but additionally the semiconductor substrate on which the Ti film is deposited moved to the second chamber into which a N₂ gas is injected.
